(19) United States
(12) Patent Application Publication
(10) Pub. No.: US 2025/0336691 A1
(43) Pub. Date: Oct. 30, 2025

(54) SUBSTRATE PROCESSING APPARATUS AND SUBSTRATE PROCESSING METHOD

(71) Applicant: SCREEN Holdings Co., Ltd., Kyoto (JP)

(72) Inventors: Shuji MURAMOTO, Kyoto (JP); Yuya AKANISHI, Kyoto (JP); Tomohiro MOTONO, Kyoto (JP); Kenta TAKATSU, Kyoto (JP); Zhida WANG, Kyoto (JP); Daiki UEHARA, Kyoto (JP); Hiroo KASAMATSU, Kyoto (JP); Tomohiro FUJIWARA, Kyoto (JP); Koji OTAWA, Kyoto (JP)

(21) Appl. No.: 19/193,245

(22) Filed: Apr. 29, 2025

(30) Foreign Application Priority Data
Apr. 30, 2024 (JP) 2024-073464

(51) Int. Cl. H01L 21/67; H01L 21/02

(52) U.S. Cl. CPC H01L 21/67034; H01L 21/02101; H01L 21/67253

(57) ABSTRACT

A substrate processing method of the invention includes accommodating a substrate having an upper surface covered with a liquid film and being placed on a support member having a flat plate-like shape in a horizontal position, into an internal space of a processing chamber, filling the internal space with the processing fluid in a supercritical state, and discharging the processing fluid from the internal space. A first ejection port ejects the processing fluid in a horizontal direction toward a space between a bottom surface among wall surfaces of the processing chamber and a lower surface of the support member. Additionally, after an internal pressure of the internal space exceeds a critical pressure of the processing fluid, a second ejection port ejects the processing fluid in a horizontal direction toward a space between a ceiling surface among the wall surfaces and an upper surface of the substrate.

### CROSS REFERENCE TO RELATED APPLICATION

The disclosure of Japanese Patent Application No. 2024-073464 filed on Apr. 30, 2024 including specification, drawings and claims is incorporated herein by reference in its entirety.

### BACKGROUND OF THE INVENTION

### 1. Field of the Invention

This invention relates to a technique for processing a substrate with a processing fluid in a supercritical state inside a processing chamber, and more particularly to a supply sequence of the processing fluid into the processing chamber.

### 2. Description of the Related Art

A process of processing of various substrates such as a semiconductor substrate, a glass substrate for a display apparatus, and the like includes that of processing a surface of a substrate with various processing fluids. Although processing using a liquid such as a chemical liquid, a rinse liquid, or the like as the processing fluid has been widely performed conventionally, processing using a supercritical fluid has been put into practical use in recent years. In particular, in the processing of a substrate having a fine pattern formed on its surface, since the supercritical fluid having a surface tension lower than a liquid penetrates deep into gaps among the pattern, the processing can be performed efficiently, and further it is possible to reduce a risk of occurrence of pattern collapse due to the surface tension during drying.

In JP2023-036123A (patent literature 1) relating to the application of the present applicant, for example, a substrate having an upper surface on which a liquid film is formed and being placed on a flat plate-like support member is accommodated into a processing chamber which is a high-pressure chamber. Then, a processing fluid is introduced from a side of the substrate to an upper surface side of the substrate and a lower surface side of the support member, respectively. Further, the processing fluid is discharged from a side opposite to a direction of introducing the processing fluid, as viewed from the substrate, on the upper surface side of the substrate and the lower surface side of the support member, respectively. A laminar flow of the processing fluid is thereby formed each of above the substrate and below the support member, and the liquid covering the substrate is replaced with the processing fluid and discharged together with the processing fluid, and finally the substrate becomes dry.

On the other hand, JP2023-017577A (patent literature 2) discloses a technique in which a pressure in a processing container is raised up to a predetermined pressure by supplying a processing fluid to a lower side of a substrate and after that, the processing fluid is caused to flow along an upper surface side of the substrate, to thereby increase a processing effect.

In a case where a high-pressure processing fluid is introduced into a processing chamber in which a substrate covered with a liquid film is accommodated, especially at an early stage of introduction, there is a possibility of partially losing a liquid forming the liquid film when the high flow rate processing fluid is sprayed thereto. When a substrate surface is thereby exposed, the risk of occurrence of a processing failure such as pattern collapse or the like increases. In patent literature 1, there is no mention on any solution of this problem.

Further, the technique disclosed in patent literature 2 copes with this problem by supplying the processing fluid only from the lower side of the substrate until a pressure in the processing container reaches a sufficiently high pressure. In such a configuration, however, the time required to raise the pressure up to a predetermined pressure becomes longer. When the amount of processing fluid to be supplied is increased in order to avoid this, the flow rate of the processing fluid becomes further higher and this may cause a processing failure.

Thus, in the technique for processing a substrate with a laminar flow of a processing fluid formed around the substrate, any technique for effectively suppressing occurrence of a processing failure such as pattern collapse or the like caused by the loss of a liquid film on a substrate surface due to introduction of the processing fluid has not been proposed. In this sense, in the background art, there is still room for improvement.

### SUMMARY OF THE INVENTION

This invention is intended to solve the above-described problem, and in the technique for processing a substrate with a processing fluid in a supercritical state inside a processing chamber, and relates to a technique which makes it possible to reduce a processing failure that may be caused by introducing a high flow rate processing fluid, and can be performed in a short time.

One aspect of this invention is intended for a substrate processing method for processing a substrate with a processing fluid in a supercritical state, and the substrate processing method includes accommodating the substrate having an upper surface covered with a liquid film and being placed on a support member having a flat plate-like shape in a horizontal position, into an internal space of a processing chamber, filling the internal space with the processing fluid in a supercritical state, and discharging the processing fluid from the internal space.

Herein, a side wall surface among wall surfaces of the processing chamber forming the internal space, is provided with a first ejection port which ejects the processing fluid in a horizontal direction toward a space between a bottom surface among the wall surfaces and a lower surface of the support member and a second ejection port which ejects the processing fluid in a horizontal direction toward a space between a ceiling surface among the wall surfaces and an upper surface of the substrate.

Then, in the filling process, the processing fluid is pressed and supplied into the internal space from the first ejection port to thereby raise a pressure in the internal space, and after an internal pressure of the internal space exceeds a critical pressure of the processing fluid, supply of the pressed processing fluid into the internal space from the second ejection port is started, besides supply of the processing fluid from the first ejection port.

Further, another aspect of this invention is intended for a substrate processing apparatus for processing a substrate with a processing fluid in a supercritical state, and the substrate processing apparatus includes a support member which has a flat plate-like shape and on which the substrate is placed, a processing chamber which has an internal space in which the support member is accommodated together with the substrate in a horizontal position, a fluid supplier which supplies the processing fluid into the internal space, a fluid discharger which discharges the processing fluid from the internal space and a controller which controls the fluid supplier.

Herein, a side wall surface among wall surfaces of the processing chamber forming the internal space, is provided with a first ejection port which ejects the processing fluid in a horizontal direction toward a space between a bottom surface among the wall surfaces and a lower surface of the support member and a second ejection port which ejects the processing fluid in a horizontal direction toward a space between a ceiling surface among the wall surfaces and an upper surface of the substrate.

Then, when the support member on which the substrate is placed is accommodated into the internal space, the control part controls the fluid supplier to start supply of the processing fluid into the internal space from the first ejection port to thereby raise a pressure in the internal space, and to start supply of the processing fluid into the internal space from the second ejection port, besides supply of the processing fluid from the first ejection port, after an internal pressure of the internal space exceeds a critical pressure of the processing fluid.

In the invention thus configured, at an early stage of introduction of the processing fluid into the processing chamber, the processing fluid is supplied to the space below the support member. Then, after the internal pressure in the processing chamber exceeds the critical pressure of the processing fluid, the supply of the processing fluid to the space above the substrate is started. Since the internal space is filled with the processing fluid having a pressure not lower than the critical pressure at this point in time, the problem that the liquid film on the substrate is blown off by the processing fluid supplied along the upper surface of the substrate can be avoided. For this reason, it is possible to effectively prevent occurrence of a processing failure when the liquid film is lost and the substrate surface is thereby exposed.

In the technique for processing a substrate with a processing fluid in a supercritical state, the internal pressure in the processing chamber is finally raised up to a pressure sufficiently higher than the critical pressure. In the invention, since the pressure can be further raised by performing not only the supply of the processing fluid simply to below the substrate but also the supply of the processing fluid to above the substrate, it is possible to shorten the time required to raise the pressure in the internal space up to a pressure necessary for the process.

As described above, in the present invention, the supply of the processing fluid to the space below the substrate is first started, and after the internal pressure in the processing chamber exceeds the critical pressure, the processing fluid is also supplied to the space above the substrate. For this reason, it is possible to shorten the time required for the internal pressure to reach a desired pressure, and moreover possible to reduce the processing failure caused by spraying of the processing fluid.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 is a view showing a schematic configuration of an exemplary substrate processing apparatus;

FIG. 2 is a flow chart showing an overview of a process performed by the substrate processing apparatus;

FIG. 3 is a timing chart showing a state change of each of apparatus components in the process;

FIG. 4 is a timing chart showing a first variation of a supercritical drying process;

FIG. 5 is a timing chart showing a second variation of the supercritical drying process; and

FIG. 6 is a timing chart showing a third variation of the supercritical drying process.

### DETAILED DESCRIPTION OF THE PREFERRED EMBODIMENTS

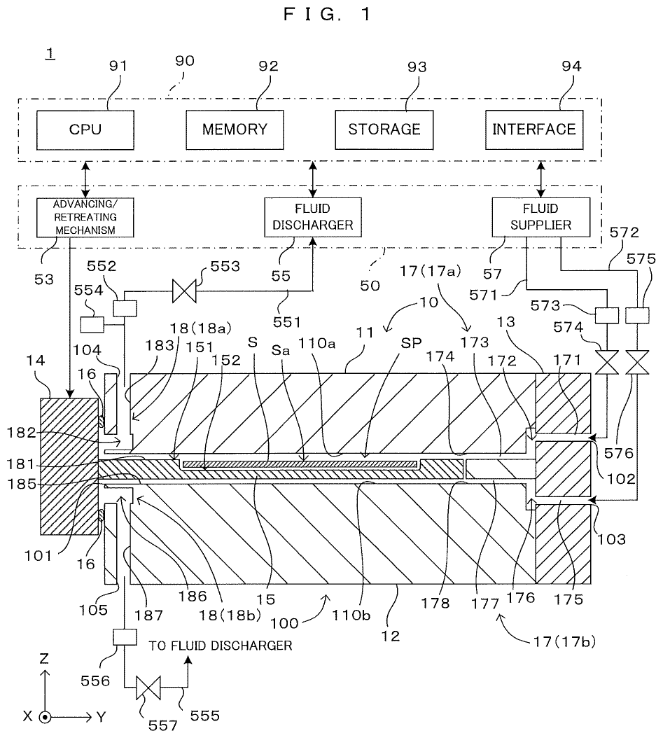

FIG. 1 is a view showing a schematic configuration of an exemplary substrate processing apparatus according to the present invention. This substrate processing apparatus 1 is an apparatus for processing surfaces of various substrates such as semiconductor substrates using supercritical fluids. To show directions in each figure in a unified manner below, an XYZ orthogonal coordinate system is set as shown in FIG. 1. Here, an XY plane represents a horizontal plane. A Z direction represents a vertical direction, and more specifically, a (−Z) direction represents a vertically downward direction.

Various substrates such as semiconductor wafers, glass substrates for photomask, glass substrates for liquid crystal display, glass substrates for plasma display, substrates for FED (Field Emission Display), substrates for optical disk, substrates for magnetic disk, and substrates for magneto-optical disk can be adopted as the “substrate” in this embodiment. A substrate processing apparatus used to process a semiconductor wafer is mainly described as an example with reference to the drawings. But the substrate processing apparatus can be adopted also to process various substrates illustrated above.

The substrate processing apparatus 1 includes a processing unit 10, a supply unit 50 and a control unit 90. The processing unit 10 serves as an execution subject of a supercritical drying process. The supply unit 50 supplies chemical substances and power necessary for the process to the processing unit 10.

The control unit 90 realizes a predetermined process by controlling these components of the apparatus. For this purpose, the control unit 90 includes a CPU 91, a memory 92, a storage 93, an interface 94, and the like. The CPU 91 executes various control programs. The memory 92 temporarily stores processing data. The storage 93 stores the control programs to be executed by the CPU 91. The interface 94 exchanges information with a user and an external apparatus. Operations of the apparatus to be described later are realized by the CPU 91 causing each component of the apparatus to perform a predetermined operation by executing the control program written in the storage 93 in advance.

The processing unit 10 has a processing chamber 100. The processing chamber 100 includes a first member 11, a second member 12 and a third member 13 and each of these is made of metal block. The first member 11 and the second member 12 are combined in vertical direction by an unillustrated fixing member. The third member 13 is combined from the (+Y) side of the first member 11 and the second member 12 by an unillustrated fixing member. In this way, the processing chamber 100 having a hollow inside is constructed. An internal space inside this hollow serves as a processing space SP where the processing of the substrate S is performed. A substrate S to be processed is carried into the processing space SP to be processed. A slit-like aperture 101 elongated in an X direction is formed in a (−Y) side surface of the processing chamber 100. The processing space SP communicates with an outside space via the aperture 101.

A lid member 14 is provided on the (−Y) side surface of the processing chamber 100 to close the aperture 101. A support tray 15 in the form of a flat plate is attached in a horizontal posture to a (+Y) side surface of the lid member 14. An upper surface of the support tray 15 serves as a support surface on which the substrate S can be placed. More specifically, the support tray 15 has a structure that a recess portion 152 formed slightly larger than a planar size of the substrate S is provided to the approximately flat upper surface 151. The substrate S is accommodated in the recess 152 and held at a predetermined position on the support tray 15. The substrate S is held with a surface to be processed (hereinafter, it may be abbreviated as “substrate surface” or “surface”) Sa facing up. At this time, it is desirable that the upper surface 151 of the support tray 15 and the substrate surface Sa form a same or approximately same plane.

The lid member 14 is supported horizontally movably in a Y direction by an unillustrated support mechanism. The lid member 14 is movable toward and away from the processing chamber 100 by an advancing/retreating mechanism 53 provided in the supply unit 50. Specifically, the advancing/retreating mechanism 53 includes a linear motion mechanism such as a linear motor, a linear guide, a ball-screw mechanism, a solenoid, an air cylinder, or the like. Such a linear motion mechanism moves the lid member 14 in the Y direction. The advancing/retreating mechanism 53 operates in response to a control command from the control unit 90.

If the support tray 15 is pulled out from the processing space SP to outside via the aperture 101 by a movement of the lid member 14 in a (−Y) direction, the support tray 15 is accessible from outside. Specifically, it becomes possible to place the substrate S on the support tray 15 and take out the substrate S placed on the support tray 15. On the other hand, the lid member 14 moves in a (+Y) direction, whereby the support tray 15 is accommodated into the processing space SP. If the substrate S is placed on the support tray 15, the substrate S is carried into the processing space SP together with the support tray 15.

In the supercritical drying processing mainly for the purpose of drying the substrate while preventing pattern collapse due to a surface tension of the liquid, the substrate S is carried in with the surface Sa covered with a liquid film to prevent the exposure of the surface Sa and the occurrence of pattern collapse. An organic solvent having a relatively low surface tension such as isopropyl alcohol (IPA) or acetone can be suitably used as the liquid for constituting the liquid film.

The lid member 14 moves in the (+Y) direction to close the aperture 101, whereby the processing space SP is sealed. A sealing member 16 is provided between the (+Y) side surface of the lid member 14 and the (−Y) side surface of the processing chamber 100 and an airtight state of the processing space SP is maintained. The seal member 16 can be made of an elastic resin material with an annular shape, a rubber material, for example. Further, the lid member 14 is fixed to the processing chamber 100 by an unillustrated lock mechanism. The substrate S is processed in the processing space SP with the airtight state of the processing space SP ensured in this way.

In this embodiment, a fluid of a substance usable for a supercritical process, e.g. carbon dioxide, is sent in a gaseous, liquid or supercritical state from a fluid supplier 57 provided in the supply unit 50 as the processing fluid. Carbon dioxide is a chemical substance suitable for the supercritical drying process in having properties of entering a supercritical state at relatively low temperature and low pressure and dissolving an organic solvent often used in substrate processing well. At a critical point of carbon dioxide at which the fluid comes into the supercritical state, a pressure (critical pressure) is 7.38 MPa and a temperature (critical temperature) is 31.1° C.

More specifically, the fluid supplier 57 outputs a fluid in a supercritical state or a fluid to be brought into the supercritical state after being supplied in a gaseous or liquid state and given thereto predetermined temperature and pressure, as the processing fluid used for processing the substrate S. For example, carbon dioxide in the gaseous or liquid state is outputted in a compressed state. The processing fluid is fed under pressure into input ports 102 and 103 provided in the (+Y) side surface of the processing chamber 100, being aligned in an up-and-down direction (Z direction), to receive the processing fluid supplied from the outside into the processing chamber 100, respectively.

Specifically, the fluid supplier 57 and the input port 102 are connected to each other with a pipe 571, and a flowmeter 573 and a valve 574 are interposed in the pipe 571. When the valve 574 is opened in response to the control command from the control unit 90, the processing fluid is transferred from the fluid supplier 57 to the processing chamber 100 through the input port 102. The flowmeter 573 measures a flow rate of the processing fluid caused to flow in the pipe 571 and sends the measurement result to the control unit 90.

Similarly, the fluid supplier 57 and the input port 103 are connected to each other with a pipe 572, and a flowmeter 575 and a valve 576 are interposed in the pipe 572. When the valve 576 is opened in response to the control command from the control unit 90, the processing fluid is transferred from the fluid supplier 57 to the processing chamber 100 through the input port 103. The flowmeter 575 measures a flow rate of the processing fluid caused to flow in the pipe 572 and sends the measurement result to the control unit 90.

A flow path 17 of the processing fluid from the input ports 102 and 103 to the processing space SP serves as an introduction flow path for introducing the processing fluid supplied from the fluid supplier 57 to the processing space SP. Specifically, a flow path 171 is connected to the input port 102 disposed above the input port 103. At an end portion of the flow path 171 on a side opposite to the input port 102, provided is a buffer space 172 which is so formed as to steeply increase a flow path cross-sectional area.

A flow path 173 is further provided to connect the buffer space 172 and the processing space SP. The flow path 173 has a wide cross-sectional shape which is narrow in the up-and-down direction (Z direction) and extending long in a horizontal direction (X direction), and the cross-sectional shape is substantially constant in a flowing direction of the processing fluid. An end portion of the flow path 173 on a side opposite to the buffer space 172 serves as an ejection port 174 which is open to the processing space SP, and the processing fluid is introduced into the processing space SP from this ejection port 174.

Desirably, a height of the flow path 173 is equal to a distance between a ceiling surface 110a of the processing space SP and the substrate surface Sa with the support tray 15 accommodated in the processing space SP. Then, the ejection port 174 is open to a gap between the ceiling surface 110a of the processing space SP and the upper surface 151 of the support tray 15. For example, the ceiling surface of the flow path 173 and the ceiling surface 110a of the processing space SP may be the same plane. In this way, the ejection port 174 is opened into a slit shape elongated in the horizontal direction while bordering the processing space SP.

The flow path 171, the buffer space 172, and the flow path 173 which form an introduction flow path from the input port 102 to the ejection port 174 form an “upper-side introduction flow path 17a” integrally, serving to supply the processing fluid into a space sandwiched by the ceiling surface 110a, the upper surface 151 of the support tray 15, and the substrate surface Sa in the processing space SP.

A flow path 17 (lower-side introduction flow path 17b) of the processing fluid is also similarly formed below the support tray 15. Specifically, a flow path 175 is connected to the input port 103 disposed below the input port 102. At an end portion of the flow path 175 on a side opposite to the input port 103, provided is a buffer space 176 which is so formed as to steeply increase a flow path cross-sectional area.

The buffer space 176 and the processing space SP communicate with each other through a flow path 177. The flow path 177 has a broad cross-sectional shape which is narrow in the up-and-down direction (Z direction) and extending long in the horizontal direction (X direction), and that cross-sectional shape is substantially constant in the flowing direction of the processing fluid. An end portion of the flow path 177 on a side opposite to the buffer space 176 serves as an ejection port 178 which is open to the processing space SP, and the processing fluid is introduced into the processing space SP from this ejection port 178.

Desirably, a height of the flow path 177 is equal to a distance between a bottom surface 110b of the processing space SP and the lower surface of the support tray 15. The ejection port 178 is open to a gap between the bottom surface 110b of the processing space SP and the lower surface of the support tray 15. For example, the bottom surface 110b of the flow path 177 and the bottom surface of the processing space SP may form the same plane. In other words, the ejection port 178 is opened into a slit shape elongated in the horizontal direction, to the processing space SP. The flow path 175, the buffer space 176, and the flow path 177 which form an introduction flow path from the input port 103 to the ejection port 178 form a “lower-side introduction flow path 17b” to supply the processing fluid into a space sandwiched by the bottom surface 110b of the processing space SP and the lower surface of the support tray 15.

Desirably, the flow path 171 and the flow path 173 are arranged at positions differing from each other in the Z direction. If the flow paths 171 and 173 are at the same height, part of the processing fluid having flowed from the flow path 171 into the buffer space 172 travels straight directly into the flow path 173. This causes a risk that the flow rate or flow speed of the processing fluid flowing into the flow path 173 will differ between a position corresponding to the flow path 171 and a position not corresponding to the flow path 171 in a width direction of the flow path perpendicular to the flow direction, namely, in the X direction. This causes non-uniformity in the flow of the processing fluid in the X direction flowing from the flow path 173 into the processing space SP to become a cause for a disturbed flow.

Arranging the flow path 171 and the flow path 173 at different positions in the Z direction prevents the occurrence of such straight travel of the processing fluid from the flow path 171 to the flow path 173. As a result, it becomes possible to introduce the processing fluid in a laminar flow uniform in the width direction into the processing space SP. Same concept can be also applied to a positional relation between the flow path 175 and the flow path 177.

The processing fluid introduced through the path (introduction flow path) 17 having the foregoing configuration flows along the upper surface and the lower surface of the support tray 15 in the processing space SP and is discharged to the outside of the processing chamber through a discharge flow path 18 having a configuration described next. Both the ceiling surface 110a of the processing space SP and the upper surface 151 of the support tray 15 form horizontal planes on the (−Y) side relative to the substrate S while extending parallel to each other in facing positions with a constant gap maintained therebetween. This gap functions as an upstream portion 181 of an upper part of the discharge flow path 18 for guiding the processing fluid having flowed along the upper surface 151 of the support tray 15 and the upper surface Sa of the substrate S to the fluid discharger 55. The upstream portion 181 has a broad sectional shape narrow in the vertical direction (Z direction) and extending long in the horizontal direction (X direction).

The upstream portion 181 has an end on the opposite side to the processing space SP that is connected to buffer space 182. The buffer space 182 is space surrounded by the processing chamber 100, the lid member 14, and the seal member 16. The buffer space 182 has a width in the X direction that is substantially equal to or greater than the corresponding width of the upstream portion 181, and a height in the Z direction that is greater than the corresponding height of the upstream portion 181. Thus, the buffer space 182 has a larger flow path sectional area than the upstream portion 181.

A downstream portion 183 of an upper-side discharge flow path 18 is connected to an upper part of the buffer space 182. The downstream portion 183 is a through hole penetrating the first member 11 as an upper block forming the chamber 100. The downstream portion 183 has an upper end that forms an output port 104 opened at an upper surface of the chamber 100, and a lower end that has an opening bordering the buffer space 182.

Likewise, both the bottom surface of the processing space SP and the lower surface of the support tray 15 form horizontal planes while extending parallel to each other in facing positions with a constant gap maintained therebetween. This gap functions as an upstream portion 185 of a lower-side discharge flow path 18 for guiding the processing fluid having flowed along the lower surface of the support tray 15 to the fluid discharger 55. The upstream portion 185 at the lower side of the support tray 15 is, as the upper side of the support tray 15, connected to a downstream portion 187 of the lower-side discharge flow path via a buffer space 186.

The processing fluid flowing above the support tray 15 in the processing space SP is sent to the output port 104 through the upstream portion 181, the buffer space 182, and the downstream portion 183 forming the upper-side discharge flow path in the discharge flow path 18. The output port 104 is connected to a fluid discharger 55 with a pipe 551, and a flowmeter 552, a valve 553 and a pressure gauge 554 are interposed at some midpoint in the pipe 551. In order to reduce detection errors due to a pressure loss in the flow path, it is desirable to provide the flowmeter 552 and the pressure gauge 554 as upstream as possible in the discharge flow path.

Similarly, the processing fluid flowing below the support tray 15 in the processing space SP is sent to an output port 105 through the upstream portion 185, the buffer space 186, and the downstream portion 187 forming a lower-side discharge flow path in the discharge flow path 18. The output port 105 is connected to the fluid discharger 55 with a pipe 555, and a flowmeter 556 and a valve 557 are interposed at some midpoint in the pipe 555. Further, like in the pipe 551, a pressure gauge may be also connected to the pipe 555.

The valves 553 and 557 are controlled by the control unit 90. When the valves 553 and 557 are opened in response to the control command from the control unit 90, the processing fluid inside the processing space SP is collected into the fluid discharger 55 through the pipes 551 and 555.

Thus, in this substrate processing apparatus 1, the upstream portion 181, the buffer space 182, and the downstream portion 183 in the discharge flow path 18 and the pipe 551 form an “upper-side discharge flow path 18a” integrally, serving to discharge the processing fluid passing through on an upper surface side of the substrate S inside the processing space SP. Further, the upstream portion 185, the buffer space 186, and the downstream portion 187 in the discharge flow path 18 form a “lower-side discharge flow path 18b” integrally, serving to discharge the processing fluid passing through on the lower surface side of the support tray 15 inside the processing space SP.

Then, the upper-side discharge flow path 18a and the lower-side discharge flow path 18b are provided with the flowmeters 552 and 556 for detecting the flow rate of the fluid, respectively. As the flowmeters 552 and 556, a flowmeter based on various principles that make it possible to detect the flow rate of the fluid in the flow path can be applied, and for example, a mass flowmeter, more specifically, for example, a Coriolis flowmeter can be used.

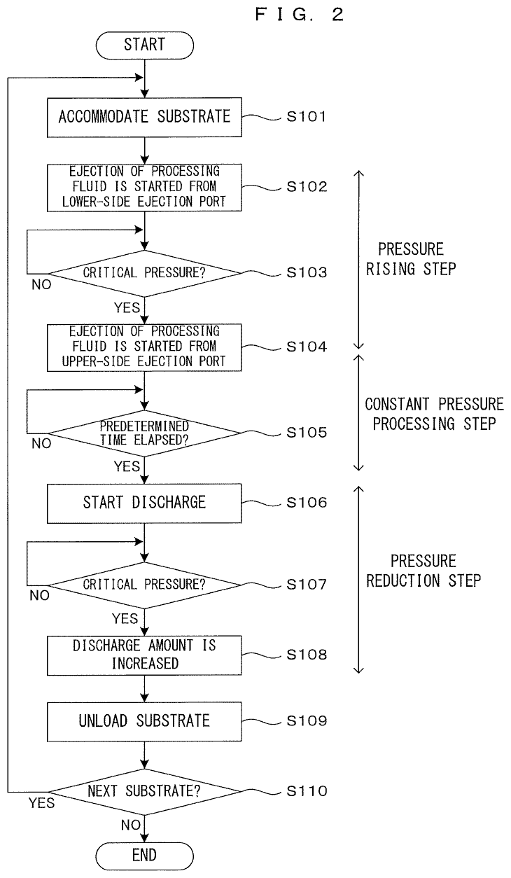

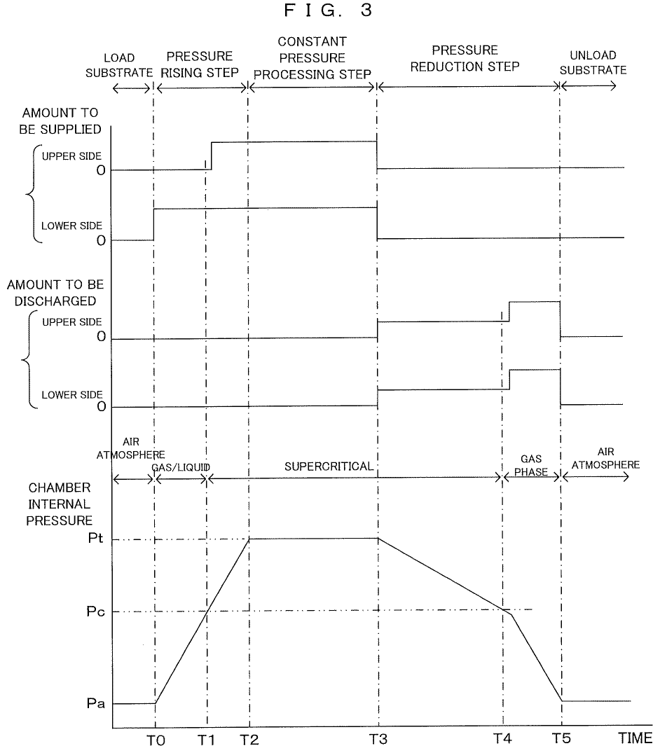

FIG. 2 is a flow chart showing an overview of a process performed by this substrate processing apparatus. FIG. 3 is a timing chart showing a state change of each of apparatus components in this process. This substrate processing apparatus 1 performs a supercritical drying process, i.e. a process of drying the substrate S cleaned with a cleaning liquid in a previous process. Specifically, this process is as follows. The substrate S to be processed is cleaned with the cleaning liquid in the previous process performed in another substrate processing apparatus constituting a substrate processing system. After that, the substrate S is conveyed to the substrate processing apparatus 1 with a liquid film formed of an organic solvent such as isopropyl alcohol (IPA) or the like formed on a surface.

For example, when a fine pattern is formed on the surface of the substrate S, the pattern may collapse due to surface tension of the liquid residually-adhering to the substrate S. Further, watermarks may remain on the surface of the substrate S due to incomplete drying. Furthermore, when the surface of the substrate S is exposed to outside air, alteration such as oxidation or the like may occur thereon. To avoid such problems beforehand, the substrate S may be conveyed with the surface (pattern forming surface) of the substrate S covered with a liquid or solid surface layer.

In a case, for example, where the cleaning liquid contains water as a main component, conveyance is carried out with the liquid film formed of a liquid having a lower surface tension than the cleaning liquid and low corrosiveness to the substrate, e.g. an organic solvent such as IPA, acetone, or the like. Specifically, the substrate S is conveyed to the substrate processing apparatus 1 while being supported in a horizontal state and having the liquid film formed on the upper surface thereof.

The substrate S conveyed by a not-shown conveying device is accommodated into the processing chamber 100 (Step S101). Specifically, the substrate S is conveyed with its pattern forming surface facing up and covered with a thin liquid film. The substrate S is passed to the support tray 15 by means of not-shown lift pins. Specifically, in a state where the lid member 14 is moved to the (−Y) side and the support tray 15 is pulled out, the lift pins move upward to above the upper surface 151 of the support tray 15 through the not-shown through holes provided in the support tray 15. When the conveying device passes the substrate S to the lift pins and the lift pins move down, the substrate S is placed on the support tray 15. When the support tray 15 and the lid member 14 integrally move in the (+Y) direction, the support tray 15 supporting the substrate S is accommodated into the processing space SP in the processing chamber 100. Finally, the aperture 101 is closed with the lid member 14.

In FIG. 3, a time period until the time TO corresponds to a loading step of the substrate. When the support tray 15 is pulled out to the outside of the chamber and the substrate S is loaded therein, the valves 553, 557, 574, and 576 are all closed. Therefore, both the amount of processing fluid to be supplied to and the amount of processing fluid to be discharged from the processing space SP are zero. Further, the pressure (hereinafter, referred to as a “chamber internal pressure”) in the processing space SP is the atmospheric pressure Pa and the inside of the processing space SP is the air atmosphere.

From this state, carbon dioxide serving as the processing fluid is introduced into the processing space SP. Specifically, the process is as follows. Among two ejection ports provided in the up-and-down direction, facing the processing space SP, firstly from a lower-side ejection port, i.e., the ejection port 178, ejection of the processing fluid is started (Step S102, time TO). Specifically, the valve 576 is opened and the processing fluid is flowed from the pipe 572 toward the ejection port 178. The processing fluid is thereby supplied into the processing space SP at a predetermined flow rate from the lower-side introduction flow path 17b (described simply as “lower side” in FIG. 3), and the processing fluid is ejected toward the space below the support tray 15 in the processing space SP.

Though the high-pressure processing fluid flows into the processing space SP having a pressure lower than that of the processing fluid, to thereby temporarily reduce the pressure of the fluid and change the phase of the processing fluid to gas or liquid, the chamber internal pressure gradually rises by continuing the supply. This state is kept until the chamber internal pressure reaches a critical pressure Pc of the processing fluid (Step S103). The chamber internal pressure can be detected by the pressure gauge 554. By comparison between detection result of the pressure gauge 554 and a threshold value set to the critical pressure Pc or a value slightly higher than the critical pressure Pc (e.g., 7.5 MPa), the determination in Step S103 can be made.

Note that it is preferable that the time T1 should be determined from the detection result of the chamber internal pressure in principle. However, if the amount of processing fluid to be introduced into the processing space SP is appropriately controlled, it is possible to estimate at what timing the chamber internal pressure reaches the critical pressure Pc, with good reproducibility. Therefore, there may be a case, for example, where a processing recipe is set by experimentally obtaining in advance a time period from the time when introduction of the processing fluid is started to the time when the chamber internal pressure reaches the critical pressure Pc. By doing so, it is determined that the chamber internal pressure reaches the critical pressure Pc when the obtained time period has elapsed from the start of supply of the processing fluid.

From the time T1 when the chamber internal pressure reaches the critical pressure Pc onward, the valve 574 is opened. Thus, the processing fluid having been flowed in the upper-side introduction flow path 17a (described simply as “upper side” in FIG. 3) at a predetermined flow rate is ejected from an upper-side ejection port 174 (Step S104). The ejected processing fluid flows in a space between the ceiling surface 110a of the processing space SP and the substrate surface Sa in the (−Y) direction. That is, a laminar flow of the processing fluid is formed along the substrate surface Sa. Since the chamber internal pressure exceeds the critical pressure Pc, the laminar flow of the processing fluid in the supercritical state is formed.

Since the processing fluid is supplied to above the substrate S and below the support tray 15 thus, the chamber internal pressure further rises. When the chamber internal pressure reaches a target pressure Pt which is set in advance, the state is kept for a predetermined time (Step S105, time T2 to time T3). By setting a pressure of the processing fluid outputted from the fluid supplier 57 to the target pressure Pt in advance, for example, it is possible to keep the chamber internal pressure at the target pressure Pt. As a value of the target pressure Pt, a sufficiently high value relative to the critical pressure Pc should be set, and for carbon dioxide having a critical pressure Pc of 7.38 MPa, for example, the target pressure Pt may be set to about 10 to 12 MPa.

As shown in FIG. 3, a time period from the time T0 to the time T2 is a period of “pressure rising step” in which the chamber internal pressure is raised with time. In the pressure rising step, before the chamber internal pressure reaches the critical pressure Pc, the processing fluid is ejected only from the lower-side ejection port 178. From the time when the chamber internal pressure reaches the critical pressure Pc onward, the processing fluid is ejected from the upper-side ejection port 174 besides from the lower-side ejection port 178.

On the other hand, a time period from the time T2 to the time T3 is a period of “constant pressure processing step” in which the chamber internal pressure is kept at the target pressure Pt. During this period, by filling the processing space SP with the processing fluid in the supercritical state, the liquid film covering the substrate surface Sa is replaced with the processing fluid and a liquid separated from the substrate S is blended into the processing fluid. During a period until the liquid is completely replaced, the constant pressure processing step is continued.

After the constant pressure processing step is continued for a predetermined time, executed is a “pressure reduction step” in which the processing fluid is discharged from the processing space SP and the chamber internal pressure is reduced (Step S106, time T3). Specifically, the valves 574 and 576 are closed and ejection of the processing fluid from the ejection ports 174 and 178 is stopped, and instead, the valves 553 and 555 are opened and the processing fluid is discharged from the processing space SP. Liquid components and/or pollution-causing substances (pollutants) which are separated from the substrate S and blended in the processing fluid are also discharged together with the processing fluid to the outside of the chamber. In the drawings, the upper-side discharge flow path 18a and the lower-side discharge flow path 18b are simply abbreviated to “upper side” and “lower side”, respectively.

The amount of discharged processing fluid at that time is relatively small and the chamber internal pressure is slowly reduced. It is thereby possible to avoid liquefaction or solidification of the processing fluid caused by temperature decrease due to sharp reduction in the pressure. Note that both the valves 553 and 555 are opened and the processing fluid is discharged from both the upper-side discharge flow path 18a and the lower-side discharge flow path 18b herein. However, the processing fluid may be discharged from any one of the upper-side discharge flow path and the lower-side discharge flow path.

When it is determined that the chamber internal pressure is reduced to the critical pressure Pc (Step S107, time T4), the amount of processing fluid to be discharged is increased (Step S108). The pressure reducing rate thereby increases. Since the phase of the processing fluid is changed to gas phase from the supercritical state at the point in time when the chamber internal pressure falls below the critical pressure Pc, no gas-liquid interface is created due to the liquefaction of the processing fluid even when the pressure reducing rate is increased. It is thereby possible to shorten the required time of the pressure reduction step. Also in this case, determination on the chamber internal pressure may be based on the detection result of the pressure gauge 554 or on the time set in advance.

From the time T5 when the chamber internal pressure is reduced to almost the atmospheric pressure Pa onward, the processed substrate S can be unloaded from the processing chamber 100 (Step S109). By carrying out the substrate S, the drying process for one substrate S is completed. When there is another substrate to be processed next, the process goes back to Step S101 and the new substrate S is received, and the above-described process is repeated (Step S110).

As described above, in the supercritical drying process of this embodiment, the supply of the processing fluid to the space below the support tray 15 supporting the substrate S inside the processing space SP is started. After the chamber internal pressure exceeds the critical pressure Pc in this state, the supply of the processing fluid to above the substrate S is additionally performed. For this reason, at the early stage of introduction of the processing fluid, i.e., in a state where the pressure inside the processing chamber 100 is low, spraying of the high flow rate processing fluid to the liquid film covering the substrate S is avoided. It is thereby possible to prevent beforehand the processing failure such as pattern collapse or the like caused by exposure of the substrate surface Sa due to the loss of the liquid film.

Aforementioned patent literature 2 also discloses that there is a problem of occurrence of the pattern collapse caused by spraying of the processing fluid, and that the supply of the processing fluid from below the substrate serves as the solution thereof. In the background art of patent literature 2, however, the pressure is raised up to the target pressure which is sufficiently higher than the critical pressure only by the supply of the processing fluid from below the substrate. On the other hand, in the present embodiment, the processing fluid is supplied also to the space above the substrate S when the chamber internal pressure reaches the critical pressure Pc. Therefore, it is possible to further shorten the required time for the chamber internal pressure to reach the target pressure.

When the processing fluid has not been brought into the supercritical state but is in a state near the supercritical state, for example, where the chamber internal pressure is about 5 to 6 MPa, recognized is a phenomenon that a large amount of processing fluid is blended into the liquid forming the liquid film to thereby largely reduce the viscosity of the liquid and the liquid film cannot be maintained to be dropped out from the substrate. When such a phenomenon occurs in a state where the environment is not filled with the supercritical fluid, there is a possibility that the substrate surface is exposed to thereby cause a processing failure.

On the other hand, in an environment in which the surface tension is extremely low and which is filled with the processing fluid in the supercritical state, in which the liquid is dissolved well, the liquid is quickly blended into the processing fluid and even a breakage of the liquid film, if occurs, does not cause a damage to the substrate. Specifically, it is thought that the cause of occurrence of the pattern collapse due to spraying of the processing fluid is that the processing fluid to be sprayed at such a high flow rate is in a liquid state or a gaseous state due to pressure drop. Then, as to the state after the processing fluid becomes supercritical, it is not necessary to consider the damage due to spraying of the processing fluid as a problem. From this point of view, in this embodiment, by starting the supply of the processing fluid to above the substrate S at the point in time when the chamber internal pressure exceeds the critical pressure Pc, it is possible to shorten the processing time as compared with that in the background art.

Further, in the above-described background art, an increase in the processing efficiency is ensured by stopping the supply of the processing fluid from below and stirring the processing fluid above the substrate after the chamber internal pressure reaches the target pressure. Unlike this, the processing fluid in the present embodiment is so supplied as to form a laminar flow in one horizontal direction both above the substrate S and below the support tray 15. By supplying the processing fluid thus, it becomes possible to suppress occurrence of a turbulent flow around the substrate S and to quickly keep the liquid, the contaminants, or the like separated from the substrate S away from the substrate S to thereby prevent redeposition thereof. Thus, the present embodiment is different from the above-described background art also in the effect of the processing fluid flowing along the substrate surface.

By the way, in the supercritical drying process of the above-described embodiment, the processing fluid is not discharged in the pressure rising step. Like in variations as shown below, however, a small amount of processing fluid may be discharged concurrently, for example, for the purpose of purging the outside air, the contaminants, or the like remaining inside the processing space SP.

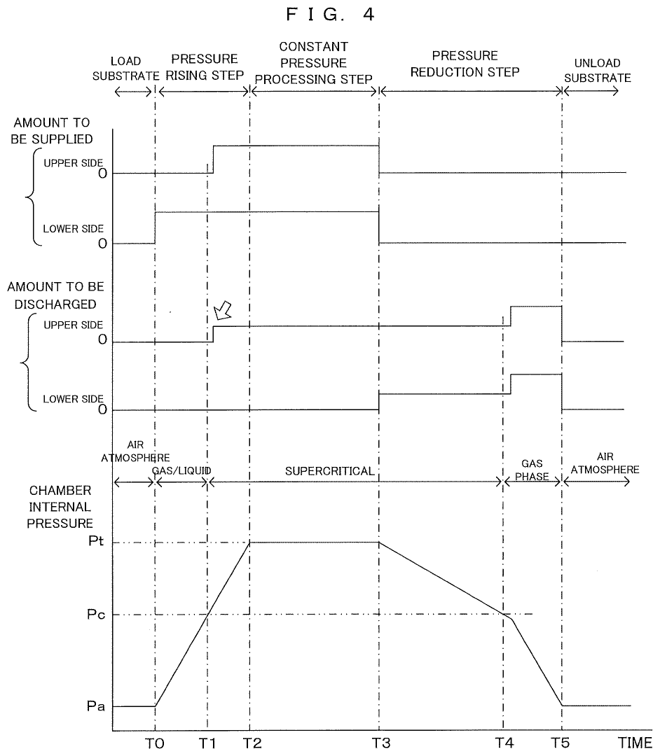

FIGS. 4 to 6 are timing charts each showing a variation of the supercritical drying process. In these figures, only the timing for starting discharge as indicated by an open arrow is different from that of the process shown in FIG. 3.

In the first variation shown in FIG. 4, discharge of the processing fluid through the upper-side discharge flow path 18a is started when the supply of the processing fluid from the upper-side introduction flow path 17a is started in the pressure rising step. Since the liquid forming the liquid film is blended in the processing fluid flowing above the substrate S, by starting the discharge of the processing fluid from the upper-side discharge flow path 18a after the processing fluid becomes supercritical, it is possible to quickly discharge the liquid components separated from the substrate S to the outside of the chamber. It is thereby possible to reduce the liquid components remaining inside the chamber in the later constant pressure processing step, to thereby increase the replacement efficiency.

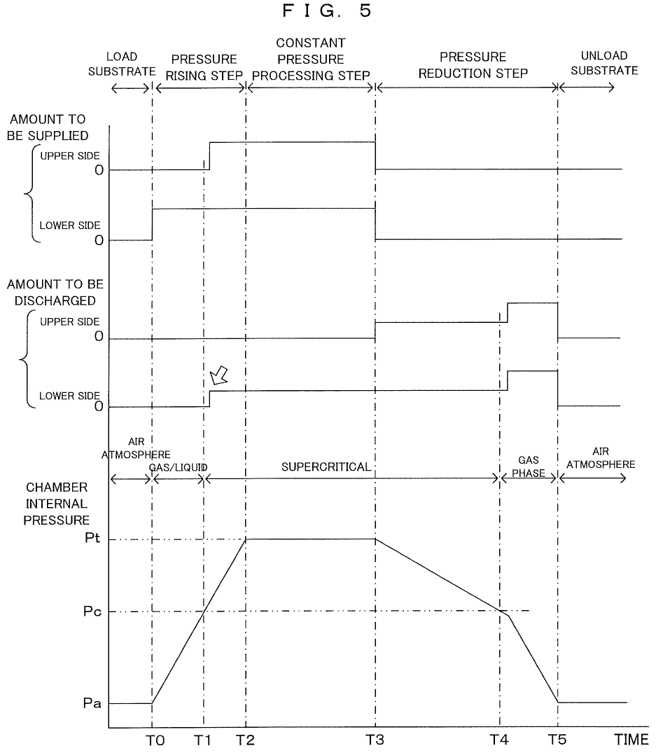

In the second variation shown in FIG. 5, discharge of the processing fluid through the lower-side discharge flow path 18b instead of the upper-side discharge flow path 18a is started when the supply of the processing fluid from the upper-side introduction flow path 17a is started in the pressure rising step. There is some case where part of the liquid forming the liquid film is dropped due to vibration in loading of the substrate and/or the reduction in the viscosity caused by mixing of the processing fluid therein below the support tray 15 inside the processing space SP. It becomes possible to quickly remove such liquid components by discharging from the space below the support tray 15.

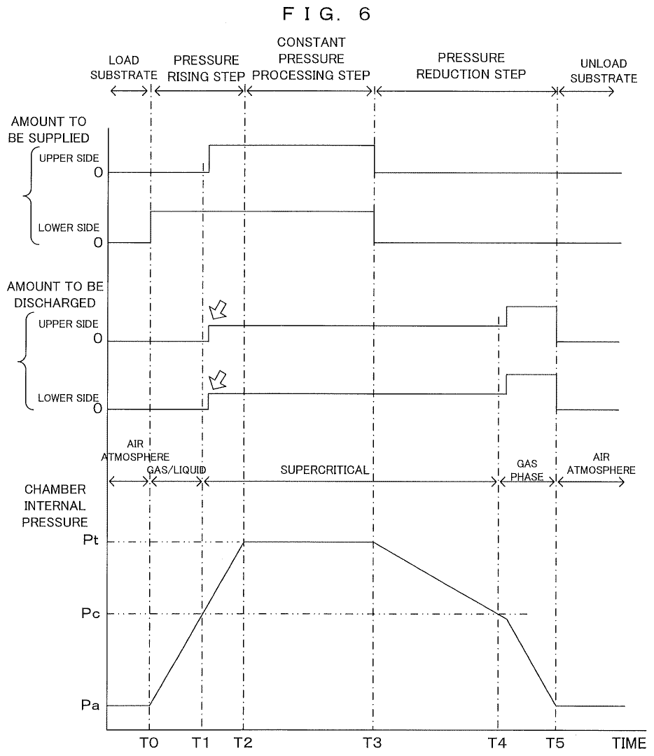

Further, in the third variation shown in FIG. 6, in the combination between the first and second variations, the processing fluid is discharged from both the upper-side discharge flow path 18a and the lower-side discharge flow path 18b. Therefore, both the effects produced by the above-described first and second variations can be obtained.

Furthermore, by adjusting the balance between the amount of processing fluid to be supplied and the amount of processing fluid to be discharged in the pressure rising step, the pressure rising rate can be managed. Moreover, such an adjustment can be performed individually in the space above the substrate S and in the space below the support tray 15 inside the processing space SP. Note that, in any one of the variations, it is not preferable that the discharge is performed prior to the time T1 when the processing fluid becomes supercritical since this reduces the pressure rising rate before the processing fluid is brought into the supercritical state, to thereby rather increase the risk of liquid film breakdown.

As described above, in the substrate processing apparatus 1 of the above-described embodiment, the processing space SP inside the processing chamber 100 corresponds to an “internal space” of the present invention. Further, in the processing chamber 100, the lower-side ejection port 178 corresponds to a “first ejection port” of the present invention and the upper-side ejection port 174 corresponds to a “second ejection port” of the present invention. Furthermore, the lower-side discharge flow path 18b and the upper-side discharge flow path 18a serve as a “first discharge flow path” and a “second discharge flow path” of the present invention, respectively.

Further, in the above-described embodiment, the support tray 15 serves as a “support member” of the present invention. Furthermore, the control unit 90 serves as a “control part” of the present invention. Further, in the supercritical drying process shown in FIG. 2, Step S101 corresponds to an “accommodating process”, Steps S102 to S105 correspond to a “filling process”, and Steps $106 to S108 correspond to a “discharging process”. Furthermore, in the above-described embodiment, the critical pressure Pc corresponds to a “first pressure” of the present invention and the target pressure Pt corresponds to a “second pressure” of the present invention.

Note that the invention is not limited to the embodiments described above and various changes other than the aforementioned ones can be made without departing from the gist of the invention. For example, in the above-described embodiment, for explanation of the principle, as a value corresponding to the “first pressure” of the present invention, the critical pressure Pc of carbon dioxide serving as the processing fluid is used. In an actual processing, however, in order to more reliably secure that the processing fluid is in the supercritical state regardless of the effect of measurement errors or the like, it is preferable to use a value slightly higher than the critical pressure (for example, 7.5 MPa relative to the critical pressure of carbon dioxide, i.e., 7.38 MPa) as the value of the first pressure.

Furthermore, in the supercritical drying process of the above-described embodiment, for example, the constant pressure processing step and the pressure reduction step are provided after the pressure rising step and moreover the pressure reducing rate is changed in two stages in the pressure reduction step. However, since the present invention has a characteristic feature in the process in which the chamber internal pressure is raised from almost the atmospheric pressure up to the target pressure higher than the critical pressure, processing details before and after the above process are not limited to those described above.

Further, in the substrate processing apparatus 1 of the above-described embodiment, the measuring instruments for measuring the flow rate and the pressure of the processing fluid are provided. In a case, however, where the processing can be performed with high reproducibility by using a processing recipe based on results of preliminary experiments or the like, at least some of these measuring instruments may be omitted. As a matter of course, for the purpose of monitoring if the processing in accordance with the recipe is performed, these measuring instruments can be effectively used.

Furthermore, various chemical substances, set values, or the like used in the processing of the above-described embodiment are only some examples, and various others can be used instead of these if those substances, values, or the like conform to the technical idea of the present invention described above.

As the specific embodiment has been exemplarily shown above, in the substrate processing method of the present invention, there may be a case, for example, where the filling process has a configuration in which the supply of the processing fluid from the first ejection port is started and then after the pressure in the internal space reaches the first pressure not lower than the critical pressure, the supply of the processing fluid from the second ejection port is started, and after the supply of the processing fluid from the second ejection port is started, the discharging process is executed after the pressure in the internal space reaches the second pressure higher than the first pressure.

According to such a configuration, it is possible to determine the timing of starting the ejection from the second ejection port and the timing of starting the discharging process on the basis of the comparison between the internal pressure of the processing chamber and a value set in advance (the first pressure, the second pressure).

Further, for example, the discharging process may be executed after the time period while the pressure in the internal space is not lower than the second pressure has elapsed for a predetermined time. Thus, by continuing the state where the pressure inside the processing chamber is higher than the critical pressure, it is possible to sufficiently replace the liquid adhering to the substrate, to be thereby removed from the substrate.

Furthermore, for example, the processing fluid being pressed to a pressure higher than the critical pressure may be supplied to the first ejection port and the second ejection port. According to such a configuration, the processing fluid is supplied, with its pressure sufficiently raised, and the supercritical state can be achieved in a short time in the internal space of the processing chamber.

In this case, the processing fluid may be supplied to the first ejection port and the second ejection port at a temperature higher than the critical temperature. According to such a configuration, it is possible to immediately supply the processing fluid in the supercritical state into the internal space. Further, it is further possible to change the phase of the processing fluid to an arbitrary phase by pressure adjustment as necessary.

Further, in the discharging process, for example, the processing fluid may be discharged from a side opposite to the first ejection port across the substrate in the internal space, or the processing fluid may be discharged from a side opposite to the second ejection port across the substrate in the internal space. According to such a configuration, since the processing fluid forms a laminar flow flowing in one direction in the internal space, it is possible to prevent the liquid components and the contaminants which are moved from the substrate to the processing fluid from being redeposited on the substrate.

Furthermore, also in the substrate processing apparatus in accordance with the present invention, it is preferable that the first ejection port and the second ejection port should be provided in the same direction as viewed from the substrate in a side view. According to such a configuration, in the internal space, the flow of the processing fluid in the same direction is formed both above the substrate and below the support member, and the occurrence of turbulent flow which may cause substrate contamination is suppressed.

In this case, there may be a configuration where the first discharge flow path for discharging the processing fluid from a side opposite to the first ejection port across the substrate in the internal space and the second discharge flow path for discharging the processing fluid from a side opposite to the second ejection port across the substrate in the internal space are provided, and the fluid discharger discharges the processing fluid from the internal space through the first discharge flow path and the second discharge flow path. According to such a configuration, it is possible to make the flow of the processing fluid forming the laminar flow much smoother and effectively prevent contamination of the substrate due to the turbulent flow.

Further, there may be a configuration where the control part controls the fluid discharger to perform discharge of the processing fluid through the first discharge flow path and discharge of the processing fluid through the second discharge flow path independently of each other. According to such a configuration, depending on the purpose, it is possible to properly use the discharge of the processing fluid from the space above the substrate and the discharge of the processing fluid from the space below the support member.

This invention can be applied to techniques in general for processing a substrate with a supercritical processing fluid inside a processing chamber. For example, this invention can be applied to a substrate drying process for drying a substrate such as a semiconductor substrate or the like with a supercritical fluid.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A substrate processing method for processing a substrate with a processing fluid in a supercritical state, comprising:
accommodating the substrate having an upper surface covered with a liquid film and being placed on a support member having a flat plate-like shape in a horizontal position, into an internal space of a processing chamber;
filling the internal space with the processing fluid in a supercritical state; and
discharging the processing fluid from the internal space,
wherein a side wall surface among wall surfaces of the processing chamber forming the internal space, is provided with:
a first ejection port which ejects the processing fluid in a horizontal direction toward a space between a bottom surface among the wall surfaces and a lower surface of the support member; and
a second ejection port which ejects the processing fluid in a horizontal direction toward a space between a ceiling surface among the wall surfaces and an upper surface of the substrate,
in the filling process,
the processing fluid is pressed and supplied into the internal space from the first ejection port to thereby raise a pressure in the internal space, and
after an internal pressure of the internal space exceeds a critical pressure of the processing fluid, supply of the pressed processing fluid into the internal space from the second ejection port is started, besides supply of the processing fluid from the first ejection port.

2. The substrate processing method according to claim 1, wherein
in the filling process, after supply of the processing fluid from the first ejection port is started, supply of the processing fluid from the second ejection port is started after a pressure in the internal space reaches a first pressure which is equal to or higher than the critical pressure, and
after supply of the processing fluid from the second ejection port is started, the discharging process is executed after the pressure in the internal space reaches a second pressure which is higher than the first pressure.

3. The substrate processing method according to claim 2, wherein
the discharging process is executed after a time period while the pressure in the internal space is not lower than the second pressure continues for a predetermined time.

4. The substrate processing method according to claim 1, wherein
the processing fluid is pressed up to a pressure higher than the critical pressure and supplied to the first ejection port and the second ejection port.

5. The substrate processing method according to claim 4, wherein
the processing fluid is supplied to the first ejection port and the second ejection port at a temperature higher than a critical temperature of the processing fluid.

6. The substrate processing method according to claim 1, wherein
in the discharging process, the processing fluid is discharged from a side opposite to the first ejection port across the substrate in the internal space.

7. The substrate processing method according to claim 1, wherein
in the discharging process, the processing fluid is discharged from a side opposite to the second ejection port across the substrate in the internal space.

8. A substrate processing apparatus for processing a substrate with a processing fluid in a supercritical state, comprising:
a support member which has a flat plate-like shape and on which the substrate is placed;
a processing chamber which has an internal space in which the support member is accommodated together with the substrate in a horizontal position;
a fluid supplier which supplies the processing fluid into the internal space;
a fluid discharger which discharges the processing fluid from the internal space; and
a controller which controls the fluid supplier,
wherein a side wall surface among wall surfaces of the processing chamber forming the internal space, is provided with:
a first ejection port which ejects the processing fluid in a horizontal direction toward a space between a bottom surface among the wall surfaces and a lower surface of the support member; and
a second ejection port which ejects the processing fluid in a horizontal direction toward a space between a ceiling surface among the wall surfaces and an upper surface of the substrate,
when the support member on which the substrate is placed is accommodated into the internal space,
the controller controls the fluid supplier to start supply of the processing fluid into the internal space from the first ejection port to thereby raise a pressure in the internal space, and
to start supply of the processing fluid into the internal space from the second ejection port, besides supply of the processing fluid from the first ejection port, after an internal pressure of the internal space exceeds a critical pressure of the processing fluid.

9. The substrate processing apparatus according to claim 8, wherein
the first ejection port and the second ejection port are provided in a same direction as viewed from the substrate in a side view.

10. The substrate processing apparatus according to claim 8, wherein
a first discharge flow path for discharging the processing fluid from a side opposite to the first ejection port across the substrate in the internal space and a second discharge flow path for discharging the processing fluid from a side opposite to the second ejection port across the substrate in the internal space are provided, and
the fluid discharger discharges the processing fluid from the internal space through the first discharge flow path and the second discharge flow path.

11. The substrate processing apparatus according to claim 10, wherein
the controller controls the fluid discharger to perform discharge of the processing fluid through the first discharge flow path and discharge of the processing fluid through the second discharge flow path independently of each other.
